(19) United States
(12) Patent Application Publication
(10) Pub. No.: US 2025/0246405 A1
(43) Pub. Date: Jul. 31, 2025

(54) PLASMA PROCESSING APPARATUS AND PLASMA PROCESSING METHOD

(71) Applicant: Tokyo Electron Limited, Tokyo (JP)

(72) Inventor: Masaki TAI, Miyagi (JP)

(73) Assignee: Tokyo Electron Limited, Tokyo (JP)

(21) Appl. No.: 19/182,398

(22) Filed: Apr. 17, 2025

Related U.S. Application Data
(63) Continuation of application No. PCT/JP2023/036707, filed on Oct. 10, 2023.

(30) Foreign Application Priority Data
Oct. 19, 2022 (JP) 2022-167413

(51) Int. Cl. H01J 37/32

(52) U.S. Cl. CPC H01J 37/32174; H01J 37/3211

(57) ABSTRACT

A plasma processing apparatus includes: a plasma processing chamber; an antenna disposed in an upper portion of the plasma processing chamber or above the plasma processing chamber; an RF power source electrically connected to the antenna and for controlling a frequency of an output power; and a controller, in which the RF power source outputs a first output power having a first frequency, and a second output power having a second frequency of a smaller power than an output power having the first frequency, and the controller executes: (a) sweeping the second frequency and searching for and specifying a resonance point; and (b) tuning the first frequency to the resonance point.

### CROSS-REFERENCE TO RELATED APPLICATIONS

This application is a bypass continuation application of international application No. PCT/JP2023/036707 having an international filing date of Oct. 10, 2023 and designating the United States, the international application being based upon and claiming the benefit of priority from Japanese Patent Application No. 2022-167413, filed on Oct. 19, 2022, the entire contents of each are incorporated herein by reference.

### TECHNICAL FIELD

The present disclosure relates to a plasma processing apparatus and a plasma processing method.

### BACKGROUND

JP2020-71912A discloses a technology of igniting a plasma in a plasma processing apparatus. The plasma processing apparatus includes a power supply and a frequency controller. The frequency controller sweeps a frequency of a power supplied into a processing container by the power supply from a first frequency to a second frequency when a plasma of a processing gas is generated in the processing container.

### CITATION LIST

### Patent Documents

Patent Literature 1: JP2020-71912A

### SUMMARY

The technology according to the present disclosure efficiently generates or maintains a plasma in an inductively-coupled plasma processing apparatus.

An aspect of the present disclosure provides a plasma processing apparatus including: a plasma processing chamber; an antenna disposed in an upper portion of the plasma processing chamber or above the plasma processing chamber; an RF power source electrically connected to the antenna and configured to control a frequency of an output power; and a controller, in which the RF power source is configured to output a first output power having a first frequency, and a second output power having a second frequency of a smaller power than an output power having the first frequency, and the controller is configured to execute: (a) sweeping the second frequency and searching for and specifying a resonance point; and (b) tuning the first frequency to the resonance point.

According to the present disclosure, the plasma can be efficiently generated or maintained in the inductively-coupled plasma processing apparatus.

### BRIEF DESCRIPTION OF DRAWINGS

FIG. 1 is a diagram illustrating a configuration example of a plasma processing system according to one embodiment.

FIG. 2 is a cross-sectional view illustrating the configuration example of the plasma processing apparatus according to one embodiment.

FIG. 3 is a diagram illustrating the configuration example of the plasma processing apparatus according to one embodiment.

FIG. 4 is a flowchart illustrating an example of a plasma processing method according to one embodiment.

FIG. 5 is a diagram illustrating a state of a plasma and a control cycle in the plasma processing method according to one embodiment.

FIG. 6A is a diagram illustrating the details and the significance of the plasma processing method according to one embodiment.

FIG. 6B is a diagram illustrating the details and the significance of the plasma processing method according to one embodiment.

FIG. 6C is a diagram illustrating the details and the significance of the plasma processing method according to one embodiment.

FIG. 7A is a diagram illustrating the details and the significance of the plasma processing method according to one embodiment.

FIG. 7B is a diagram illustrating the details and the significance of the plasma processing method according to one embodiment.

FIG. 7C is a diagram illustrating the details and the significance of the plasma processing method according to one embodiment.

FIG. 8 is a flowchart illustrating an example of the plasma processing method according to one embodiment.

FIG. 9A is a diagram illustrating the details and the significance of the plasma processing method according to one embodiment.

FIG. 9B is a diagram illustrating the details and the significance of the plasma processing method according to one embodiment.

FIG. 9C is a diagram illustrating the details and the significance of the plasma processing method according to one embodiment.

FIG. 9D is a diagram illustrating the details and the significance of the plasma processing method according to one embodiment.

FIG. 9E is a diagram illustrating the details and the significance of the plasma processing method according to one embodiment.

FIG. 9F is a diagram illustrating the details and the significance of the plasma processing method according to one embodiment.

FIG. 9G is a diagram illustrating the details and the significance of the plasma processing method according to one embodiment.

FIG. 10A is a diagram illustrating the details and the significance of the plasma processing method according to one embodiment.

FIG. 10B is a diagram illustrating the details and the significance of the plasma processing method according to one embodiment.

FIG. 10C is a diagram illustrating the details and the significance of the plasma processing method according to one embodiment.

FIG. 10D is a diagram illustrating the details and the significance of the plasma processing method according to one embodiment.

FIG. 10E is a diagram illustrating the details and the significance of the plasma processing method according to one embodiment.

FIG. 10F is a diagram illustrating the details and the significance of the plasma processing method according to one embodiment.

FIG. 11A is a diagram illustrating a plasma processing method according to a comparative example.

FIG. 11B is a diagram illustrating the plasma processing method according to the comparative example.

FIG. 11C is a diagram illustrating the plasma processing method according to the comparative example.

### DETAILED DESCRIPTION

In the process of manufacturing a semiconductor device, a semiconductor substrate (hereinafter referred to as a “substrate”) is subjected to plasma processing such as etching or film formation processing. In the plasma processing, a plasma is generated by exciting a processing gas, and a wafer is processed by the plasma.

In the plasma processing, processing with high processing rate, high fineness, and high depth is required, and in order to achieve this processing, a processing method using a high-density plasma is in practical use.

For the generation of the high-density plasma, for example, a plasma processing apparatus (etching apparatus) of an inductively-coupled (ICP) method using an induction coil is used. An inductance component of the induction coil and a capacitance component of the plasma configure a resonance circuit. By tuning a frequency of the power output from a source RF power source to a resonance point of the resonance circuit, an impedance between the source RF power source and the plasma is matched, so that the plasma having high power efficiency can be generated. Meanwhile, the resonance circuit of the plasma processing apparatus of the ICP method has high quality-factor characteristics (high Q characteristics) and has a narrow frequency width (resonance width) at which the impedance is matched.

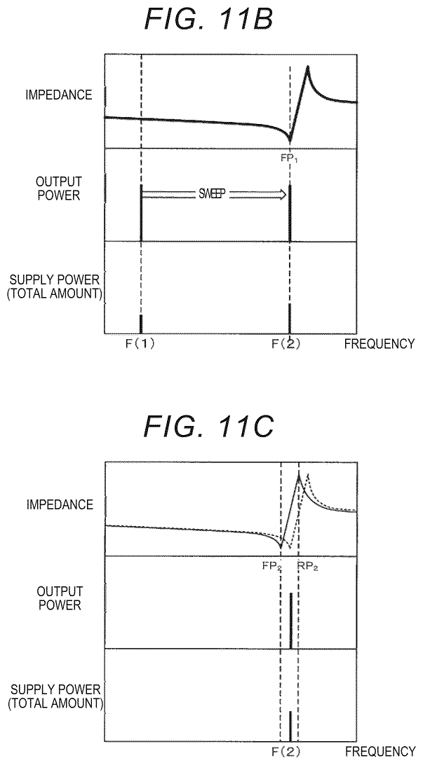

Hereinafter, an impedance matching control method according to a comparative example will be described with reference to FIGS. 11A to 11C. FIGS. 11A to 11C illustrate plasma impedance matching control via frequency control of the source RF power source (hereinafter, may be referred to as simply “matching control”) according to the comparative example.

In FIG. 11A, in the matching control according to the comparative example, each graph represents, from the top, an impedance between the source RF power source and the plasma, a source RF power (output power) output from the source RF power source, and a power (supply power) supplied to the plasma. In each graph, a horizontal axis represents a frequency value. In a graph of the impedance, a vertical axis represents an impedance value. In a graph of the output power and the supply power, a vertical axis represents a power value. A frequency of the output power before the sweep is F(1). Further, the resonance point of the impedance includes a first resonance point FP₁ and a second resonance point FP₂, and an antiresonance point includes a first antiresonance point RP₁ and a second antiresonance point RP₂.

The supply power with respect to the plasma is the sum of the output powers of the respective frequencies absorbed by the plasma among the output powers output from the source RF power source. When the frequency F of the output power deviates from the first resonance point FP₁, impedance mismatching occurs, and a part of the output power is not absorbed by the plasma and lost. Therefore, it is required in the matching control to supply the output power to the plasma with the smallest losses by tuning the frequency F of the output power to the first resonance point FP₁ and matching the impedance.

Further, it is also important to supply the supply power enough to maintain the plasma. Here, when the frequency F of the output power changes from the first resonance point FP₁ toward the first antiresonance point RP₁ during the sweep or the like, the impedance rapidly increases. The increase in the impedance causes a decrease in the supply power with respect to the plasma, and when the supply power falls below a predetermined level, the plasma may not be maintained. Therefore, it is required to prevent the rapid increase in the impedance caused by the frequency F of the output power toward the first antiresonance point RP₁ side.

FIG. 11B illustrates a control step of sweeping the power output from the source RF power source from the frequency F(1) to the frequency F(2), and F(2) is tuned to the first resonance point FP₁ in the matching control according to the comparative example. In one control cycle, when the frequency F of the power output from the source RF power source and the first resonance point FP₁ are tuned, the impedance matching is established, and the supply power with respect to the plasma is maximized. In the control cycle, the sweep ends when the supply power with respect to the plasma is maximized. After the sweep ends, control of monitoring the supply power with respect to the plasma and periodically adjusting the frequency F of the output power such that the supply power is always maximized is performed. As an example, when the supply power is equal to or lower than a desired threshold, the control cycle proceeds to the next control cycle, and the sweep is executed again. Here, the impedance of the plasma is not always constant, and varies due to a change in the supply power, a pressure in the plasma space, or a gas mixture ratio.

FIG. 11C illustrates a state where the resonance point of the impedance shifts from the first resonance point FP₁ to the second resonance point FP₂ due to the variation in the plasma in the matching control according to the comparative example. In this state, the frequency F(2) of the output power tuned to the first resonance point FP₁ is not tuned to the second resonance point FP₂, a degree of impedance matching is reduced, and the supply power with respect to the plasma decreases.

As in the description with respect to FIGS. 11A to 11C, in the comparative example, the matching control is performed by controlling the frequency of a single output power. Specifically, both the search and the specification for the resonance point and the tuning control are performed by frequency sweeping of the output power from the source RF power source that maintains the plasma. In the search for such a resonance point, since the frequency of the output power is moved before and after the resonance point to search for the frequency at which the supply power is maximized, the frequency may inevitably move from the resonance point side to the antiresonance point side in its operation.

The present inventor has intensively studied the matching control according to the comparative example, and has obtained the following finding. That is, when the antiresonance point moves in a direction toward the frequency F of the output power due to the variation in the impedance, the impedance rapidly increases. In particular, when there are high Q resonance characteristics, the change is more remarkable. As illustrated in FIG. 11C, even when the frequency F of the output power slightly deviates from the second resonance point FP₂ in a direction of the second antiresonance point RP₂, the supply power required for maintaining the plasma cannot be supplied. Therefore, there is a problem in that the decrease in the supply power with respect to the plasma easily occurs due to the control operation in which the frequency F of the output power moves from the resonance point side to the antiresonance point side or the behavior in which the resonance point moves.

The inventor has further obtained the following finding. That is, there is a problem that over-control may be easily caused by factors such as measurement errors of various sensors or measuring instruments in the matching control, control amounts or control errors of frequencies during the search, or the variation in pressure or gas conditions inside the chamber. With the over-control, there is a problem in that the frequency of the output power moves by an unexpected amount to the antiresonance point side during the matching control, so that the plasma may be misfired.

Further, in the process of processing the substrate, in the related art, a static method has been performed in which the supply of the output power from the source RF power source is once stopped and the plasma is lost before conditions in the chamber such as a pressure variation, a mixture ratio of gases, and a flow rate are changed. In the static method, after the plasma is lost, the supply of the output power from the source RF power source is restarted to reignite the plasma after the setup in the chamber in accordance with the conditions inside the chamber is completed. However, in recent years, in order to perform more complicated processing, it has been required to perform a dynamic method of continuously changing the conditions inside the chamber while maintaining the plasma.

The present inventor has intensively studied the process of processing the substrate according to the comparative example, and has obtained the following finding. That is, the dynamic method described above involves a larger variation in the impedance when the conditions inside the chamber are changed than the static method described above, and thus there is a problem in that it is difficult to stably match the impedance in the matching control according to the comparative example.

In view of the above-described problems, the present disclosure provides a plasma processing method of performing impedance matching control with further improved stability.

Hereinafter, a configuration of a substrate processing apparatus according to the present embodiment will be described with reference to the drawings. The same reference numerals will be given to elements having substantially the same functional configurations throughout the specification, and redundant description thereof will be omitted.

### <Plasma Processing System>

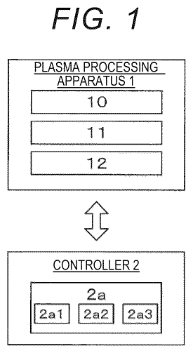

FIG. 1 is a diagram for explaining an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively-coupled plasma (CCP), inductively-coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The controller 2 may include an RF controller 70, which will be described later. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

### <Plasma Processing Apparatus>

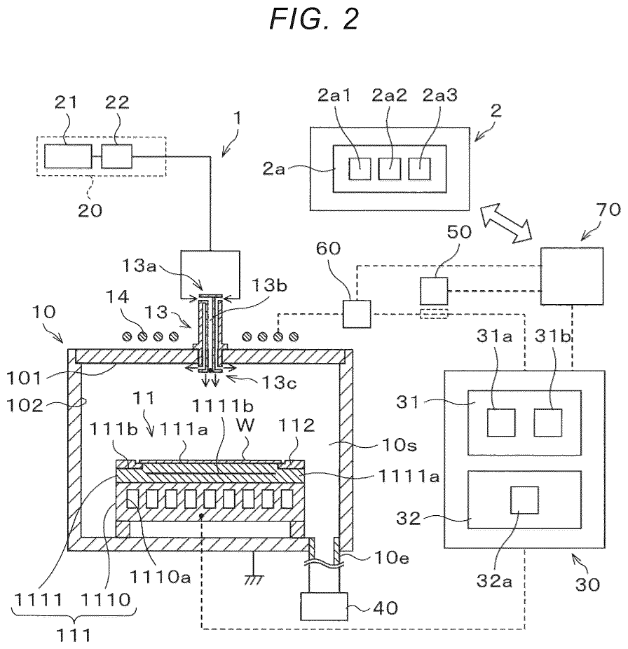

Hereinafter, a configuration example of an inductively-coupled plasma processing apparatus 1 as an example of the plasma processing apparatus 1 will be described. FIG. 2 is a diagram illustrating the configuration example of the inductively-coupled plasma processing apparatus 1.

The inductively-coupled plasma processing apparatus 1 includes the plasma processing chamber 10, the gas supply 20, a power source 30, and the exhaust system 40. The plasma processing chamber 10 includes a dielectric window 101. Further, the plasma processing apparatus 1 includes the substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s defined by the dielectric window 101, a sidewall 102 of the plasma processing chamber 10, and the substrate support 11. The plasma processing chamber 10 is grounded.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112.

In one embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 11a. In one embodiment, the ceramic member 1111a also has the annular region 1l1b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power source 31 and/or a DC power source 32, which will be described later, may be disposed in the ceramic member 1111a. In this case, at least one RF/DC electrode functions as the bias electrode. The conductive member of the base 1110 and at least one RF/DC electrode may function as a plurality of bias electrodes. Further, the electrostatic electrode 1111b may function as the bias electrode. Accordingly, the substrate support 11 includes at least one bias electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The gas introduction unit is configured to introduce at least one processing gas from the gas supply 20 into the plasma processing space 10s. In one embodiment, the gas introduction unit includes a center gas injector (CGI) 13. The center gas injector 13 is disposed above the substrate support 11 and attached to a center opening formed in the dielectric window 101. The center gas injector 13 has at least one gas supply port 13a, at least one gas flow path 13b, and at least one gas introduction port 13c. The processing gas supplied to the gas supply port 13a passes through the gas flow path 13b and is introduced into the plasma processing space 10s from the gas introduction port 13c. The gas introduction unit may include one or more side gas injectors (SGI) attached to one or more openings formed in the sidewall 102, in addition to or instead of the center gas injector 13.

The gas supply 20 may include at least one gas source 21 and at least one flow rate controller 22. In one embodiment, the gas supply 20 is configured to supply at least one processing gas from the respective corresponding gas sources 21 to the gas introduction unit through the respective corresponding flow rate controllers 22. Each flow rate controller 22 may include, for example, a mass flow controller or a pressure-controlled flow rate controller. Further, the gas supply 20 may include at least one flow rate modulation device that modulates or pulses a flow rate of at least one processing gas. As a result, the gas pressure and the mixing ratio in the plasma processing space 10s can be adjusted to desired values.

The power source 30 includes the RF power source 31 coupled to the plasma processing chamber 10 via at least one impedance matching circuit. The RF power source 31 is configured to supply at least one RF signal (RF power) to the at least one bias electrode and the antenna 14. Accordingly, the plasma is formed from at least one processing gas supplied into the plasma processing space 10s. Accordingly, the RF power source 31 may function as at least a part of the plasma generator 12. Supplying the bias RF signal to at least one bias electrode can generate a bias potential in the substrate W to attract ions in the formed plasma to the substrate W.

In one embodiment, the RF power source 31 includes a source RF power source 31a and a bias RF power source 31b. The source RF power source 31a is coupled to the antenna 14 via at least one impedance matching circuit, and configured to generate a source RF signal (source RF power) for plasma generation and output the source RF signal (source RF power) to the antenna 14. In one embodiment, the source RF signal has a frequency within a range from 10 MHz to 150 MHz. The source RF power source 31a is configured to generate a plurality of source RF signals having different frequencies, which will be described later, and output the generated source RF signals to the antenna 14. In one embodiment, the source RF power source 31a is a variable frequency power source. The plurality of output source RF signals (hereinafter referred to as output powers) are supplied to the antenna 14. A part of the output power supplied to the antenna 14 is reflected and does not contribute to the generation or the maintenance of the plasma. Such a power will be referred to as a reflected power. Further, the power that contributes to the generation or the maintenance of the plasma will be referred to as a supply power. The details of the output power, the reflected power, and the supply power will be described later.

The bias RF power source 31b is coupled to the at least one bias electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the bias RF power source 31b may be configured to generate a plurality of bias RF signals having different frequencies. The generated one or more bias RF signals are supplied to at least one bias electrode. In various embodiments, at least one of the source RF signal and the bias RF signal may be pulsed.

The power source 30 may include the DC power source 32 coupled to the plasma processing chamber 10. The DC power source 32 includes a bias DC generator 32a. In one embodiment, the bias DC generator 32a is connected to the at least one bias electrode and configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulse may have a pulse waveform of a rectangle, a trapezoid, a triangle or a combination thereof. In one embodiment, a waveform generator for generating the sequence of voltage pulses from the DC signal is connected between the bias DC generator 32a and at least one bias electrode. Accordingly, the bias DC generator 32a and the waveform generator configure a voltage pulse generator. The voltage pulse may have a positive polarity or a negative polarity. The sequence of the voltage pulses may include one or more positive voltage pulses and one or more negative voltage pulses in one cycle. The bias DC generator 32a may be provided in addition to the RF power source 31, or may be provided instead of the bias RF power source 31b.

The antenna 14 includes one or more coils. In one embodiment, the antenna 14 may include an outer coil and an inner coil that are coaxially disposed. In this case, the RF power source 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil, respectively.

A sensor unit 50 for measuring the impedance of the plasma or the supply power is provided on an output path of the output power from the source RF power source 31a. A matcher 60 is provided on the output path of the output power, and configures a tuning circuit for matching the impedance between the source RF power source 31a and the plasma processing chamber 10 including the plasma. Further, the RF controller 70 for controlling the source RF power source 31a and the matcher 60 is provided. The RF controller 70 may be incorporated in the controller 2 and provided as a part of the controller 2.

The exhaust system 40 may be connected, for example, to a gas exhaust port 10E disposed at a bottom of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### <Tuning Circuit for Impedance Matching>

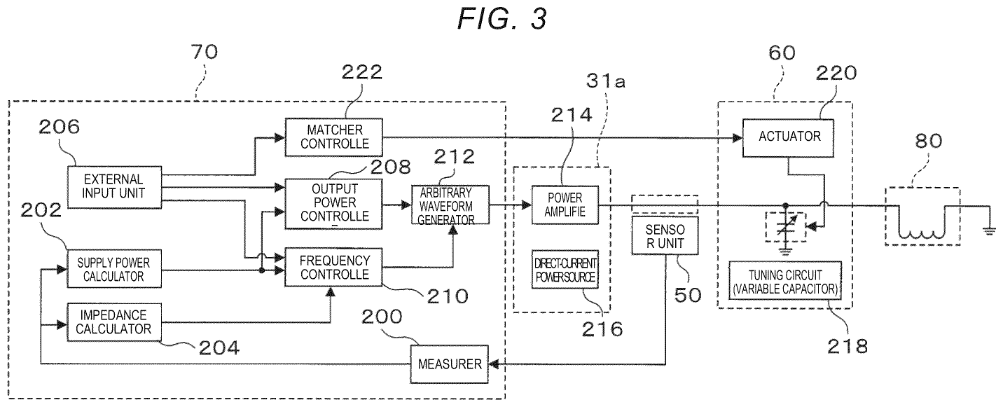

Hereinafter, a tuning circuit for matching the impedance will be described in detail with reference to FIG. 3. FIG. 3 illustrates the connection and the configurations between the source RF power source 31a, the sensor unit 50, the matcher 60, the RF controller 70, and an induction coil 80 serving as the antenna 14. In these configurations, feedback control is performed to adjust the output or the operation of the source RF power source 31a or the matcher 60 based on a difference between a command signal from the outside, for example, the controller 2 and the power measured in the sensor unit 50.

Specifically, the sensor unit 50 measures the voltage, the current, and a phase difference between the voltage and the current of the radio-frequency output, converts the measured data into an analog signal or a digital signal, and transmits the analog signal or the digital signal to a measurer 200 of the RF controller 70. After converting the measured data into the internal signals, the measurer 200 transmits the internal signals to a supply power calculator 202 and/or an impedance calculator 204. The supply power calculator 202 calculates the supply power (P) with respect to the plasma from the measurement results of the sensor unit 50. Specifically, when the voltage (RMS value) measured by the sensor unit 50 is denoted by Vrms, the current (RMS value) is denoted by Irms, and the phase difference is denoted by θ, the supply power (P) with respect to the plasma is obtained by the following expression (1).

P=Vrms×Irms×cos(θ) (1)

Similarly, the impedance calculator 204 calculates the impedance (Z) between the source RF power source 31a and the plasma processing chamber 10 from the measurement results of the sensor unit 50 by the following expression (2).

Z=Vrms/Irms (2)

Next, as an example, a command signal from the controller 2 is input to an external input unit 206. The external input unit 206 to which the command signal from the controller 2 is input transmits an output power command signal as the internal signal to an output power controller 208. The output power controller 208 calculates the output power to be output from the source RF power source 31a from the difference between the output power command signal from the external input unit 206 and the supply power measured by the sensor unit 50. Further, the external input unit 206 to which the command signal from the controller 2 is input transmits a frequency command signal as the internal signal to a frequency controller 210. The frequency controller 210 determines the supply power with respect to the plasma based on a reference frequency command signal from the external input unit 206, and calculates the output frequency for matching the impedance from the measurement results of the impedance.

Next, the results calculated by the output power controller 208 and the frequency controller 210 are transmitted to an arbitrary waveform generator 212. The arbitrary waveform generator 212 generates a waveform in which sinusoidal waves of a plurality of frequency components are superimposed based on the results calculated by the output power controller 208 and the frequency controller 210, and outputs the waveform to the source RF power source 31a. In a plasma processing method MT1 according to a first embodiment, which will be described later, the arbitrary waveform generator 212 generates a waveform in which sinusoidal waves of a plurality of frequency components including a first frequency F₁ and a second frequency F₂, which will be described later, are superimposed. In this case, the arbitrary waveform generator 212 is configured to independently control the first frequency F₁ and the second frequency F₂. In a plasma processing method MT2 according to a second embodiment, which will be described later, the arbitrary waveform generator 212 generates a waveform in which sinusoidal waves of a plurality of frequency components included in a bandwidth ΔF, which will be described later, are superimposed. In this case, the arbitrary waveform generator 212 is configured to enlarge and reduce the bandwidth ΔF.

Next, a power amplifier 214 of the source RF power source 31a amplifies the sinusoidal waves output from the arbitrary waveform generator 212 with a desired gain by the direct-current power supplied from a direct-current power source 216. The power amplifier 214 includes a plurality of FETs (field-effect transistors) for amplifying radio-frequency power, a distributor that distributes the waveform from the arbitrary waveform generator 212 to the FETs, and a combiner for combining the output powers of the FETs.

Next, the matcher 60 including a variable capacitor 218 configures a tuning circuit for matching the impedance of the plasma by the frequency of the output power from the source RF power source 31a and the capacitor component of the variable capacitor 218. As the variable capacitor 218, for example, a vacuum capacitor having high durability with respect to a high voltage generated by resonance of the impedance is used. Further, the variable capacitor 218 is connected to an actuator 220 such as an electric motor. A matcher controller 222 in the RF controller 70 adjusts the capacitance of the capacitor by driving the actuator 220 based on a variable capacitor position command signal from the external input unit 206. As a result, it is adjusted to be within a range of the frequency calculated by the frequency controller 210 during the plasma generation.

A plurality of the source RF power sources 31a and a plurality of the RF controllers 70 may be provided. As an example, a configuration may be adopted in which the source RF power source 31a serving as a main source and the source RF power source 31a serving as a sub-source are provided, and one RF controller 70 is provided for each of the main source and the sub-source. In this case, a first output power E₁ of the first frequency F₁, which will be described later, may be output from the source RF power source 31a serving as the main source, and a second output power E₂ of the second frequency F₂, which will be described later, may be output from the source RF power source 31a serving as the sub-source. Further, a plurality of RF controllers 70 except the arbitrary waveform generator 212 may be provided, and signals of a plurality of frequencies including the first frequency F₁ and the second frequency F₂, which will be described later, may be transmitted from each RF controller to one arbitrary waveform generator 212. In this case, the arbitrary waveform generator 212 may be configured to generate a waveform in which sinusoidal waves of a plurality of frequency components are superimposed, and output the waveform to one source RF power source 31a.

### First Embodiment

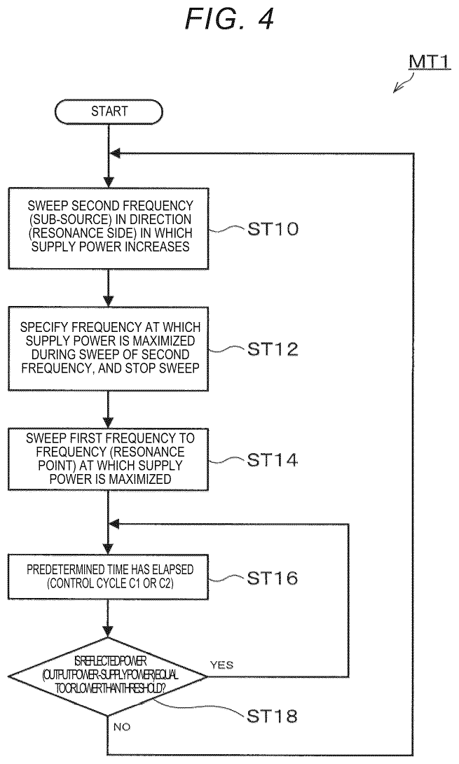

Hereinafter, the plasma processing method MT1 according to the first embodiment will be described with reference to FIGS. 4 to 7. In the plasma processing method MT1 according to the first embodiment, the first output power E₁ of the first frequency F₁ that maintains the plasma and the second output power E₂ of the second frequency F₂ are used. That is, the resonance point of the impedance is searched for and specified by using the second output power E₂ of the second frequency F₂, and the first frequency F₁ is tuned to the specified resonance point. The resonance point is the first resonance point FP₁ or the second resonance point FP₂, and the antiresonance point is the first antiresonance point RP₁ or the second antiresonance point RP₂. Hereinafter, a specific method will be described in detail.

FIG. 4 is a flowchart illustrating a schematic diagram of the plasma processing method MT1 according to the first embodiment. In FIG. 4, first, the second frequency F₂ is swept in a direction (resonance side) in which the supply power increases, and the resonance point (the first resonance point FP₁) of the impedance is searched for (step ST10). Next, the frequency at which the supply power P₂ of the second frequency F₂ is maximized is specified as the first resonance point FP₁, and the sweep of the second frequency F₂ is stopped (step ST12). Next, the first frequency F₁ is swept and tuned to the specified first resonance point FP₁ (step ST14). Next, after a desired time (any one of a first control cycle C1 or a second control cycle C2, which will be described later) has elapsed, the process proceeds to the next step (step ST16). Next, the reflected power is compared with a threshold to determine the magnitude (step ST18). When the reflected power is equal to or lower than the threshold, the process returns to step ST16. When the reflected power exceeds the threshold, it is determined that the first resonance point FP₁ moves to the second resonance point FP₂, and the process returns to step ST10. By repeating steps ST10 to ST18 to periodically perform the matching control, the first frequency F₁ can be made to follow the movement of the resonance point due to the variation in the impedance and can be tuned.

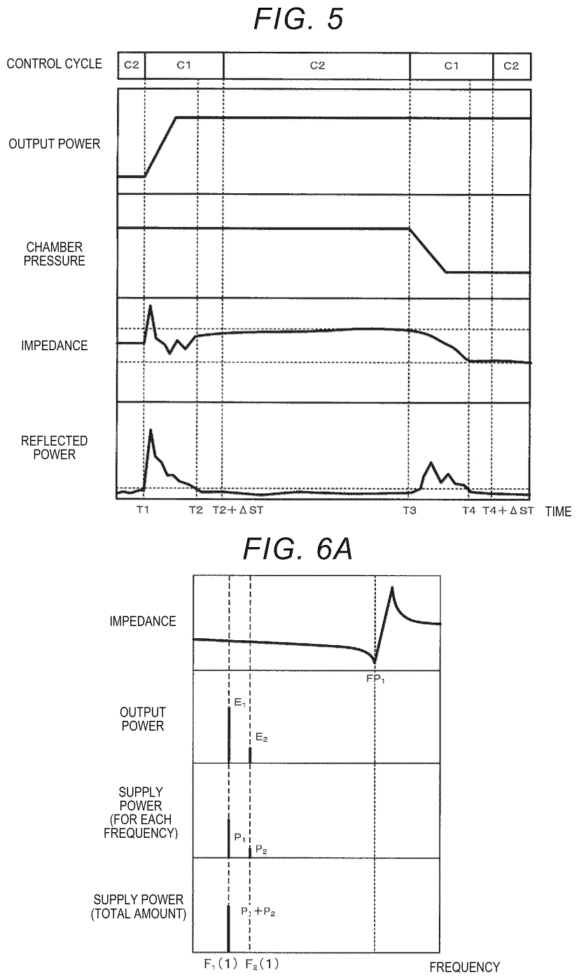

Hereinafter, the first control cycle C1 and the second control cycle C2 will be described with reference to FIG. 5. FIG. 5 illustrates the states of the impedance, the reflected power, and the control cycle of the matching control when the output power from the source RF power source 31a, or the chamber pressure (or the gas condition) is step-changed by an external command signal. The significance of the first control cycle C1 and the second control cycle C2 is the same in the second embodiment, which will be described later.

The impedance of the plasma varies depending on the step change in the output power or the pressure (or gas conditions) in the chamber, which is caused by the external command signal. Immediately after the step, the plasma is in a transient state, and the variation in the impedance at this time becomes steep. Further, over time, the plasma is changed from the transient state to a steady state, and the variation in the impedance becomes gradual. In order to stabilize the matching control, it is preferable to suppress an excessive change in the frequency of the output power. Therefore, in one embodiment, the control cycle is switched to a short cycle (C1) or a long cycle (C2) to vary a response, depending on each state of the plasma caused by the step change in the external command signal.

When a time when the output of the output power from the source RF power source 31a is started is denoted by T1, the plasma immediately after the time T1 is in the transient state. As the control cycle in the transient state, the short cycle (C1) is selected in order to respond to a steep change in the impedance. The control cycle C1 of the short cycle is, specifically, 100 sec or less. As a result, the matching control can be performed following the steep change in the impedance. A lower limit of the control cycle of the short cycle is not particularly limited, and may be, for example, 10 sec or more.

When the time reaches a time T2 when the reflected power is equal to or lower than the threshold from the time T1, the process waits for the plasma to be in the steady state, and the matching control proceeds to a step of monitoring the fact that the reflected power is equal to or lower than the threshold for a predetermined time (ΔST). After it is determined that the reflected power is constantly equal to or lower than the threshold from the time T2 to a time (T2+ΔST), the plasma is considered to be in a steady state, and the control cycle is changed from the short cycle (C1) to the long cycle (C2). The control cycle C2 of the long cycle is, specifically, 1 sec or less. As a result, the matching control can be performed following the change in the impedance in the steady state of the plasma. Further, the control cycle of the long cycle is, for example, 100 sec or more.

At a time T3, for example, when the chamber pressure is stepped, the same step as the step immediately after the time T1 is performed. In order to respond the transient state of the plasma after the step, immediately after the time T3, the long cycle (C2) shifts to the short cycle (C1). Thereafter, after the time reaches a time T4 when the reflected power is equal to or lower than the threshold, it is monitored that the reflected power is constantly equal to or lower than threshold for the time AST, and after it is determined that the reflected power is constantly equal to or lower than the threshold from the time T4 to a time (T4+ΔST), the plasma is considered to be in the steady state, and the control cycle is changed from the short cycle (C1) to the long cycle (C2).

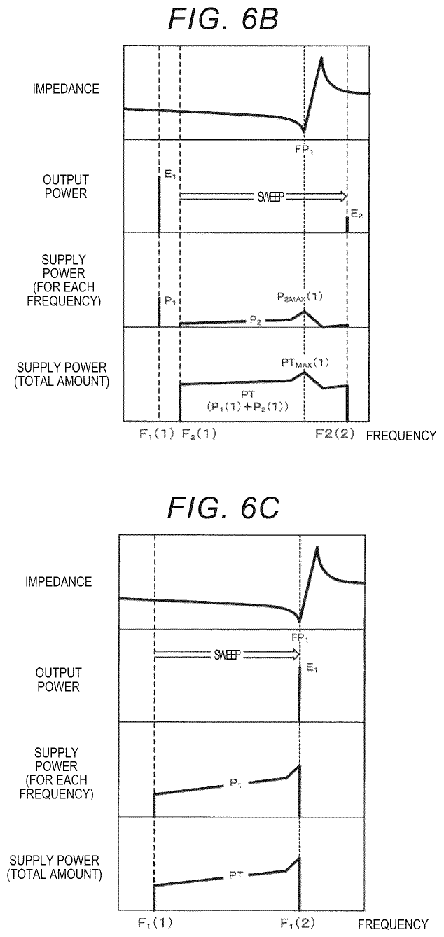

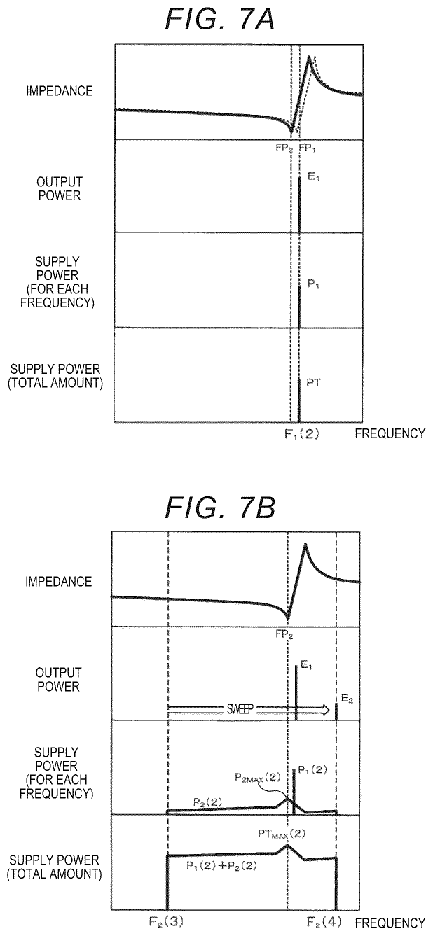

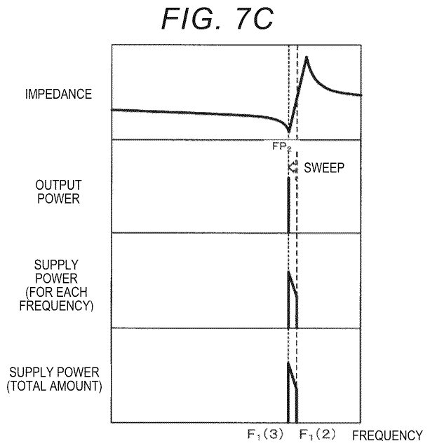

Hereinafter, the details and the significance of each step of the plasma processing method MT1 according to the first embodiment will be described with reference to FIGS. 6A to 6C and FIGS. 7A to 7C. In the drawings, the graphs illustrate, from the top, the impedance between the source RF power source 31a and the plasma, the first output power E₁ of the first frequency F₁ and the second output power E₂ of the second frequency F₂, the supply power P₁ of the first frequency F₁ and the supply power P₂ of the second frequency F₂, and a total amount PT of the supply power. The graph of the impedance is a graph for the sake of convenience of describing the details and the significance of each step of the plasma processing method MT1, and does not mean that the impedance at any frequency is measured or calculated in each step.

FIG. 6A illustrates the impedance, the first and second output powers E₁ and E₂, the supply powers P₁ and P₂, and the total amount PT of the supply power, before step ST10 is started. Since the output powers E₁ and E₂ at the respective frequencies are not tuned to the resonance point FP₁ of the impedance, a part thereof is reflected (becomes the reflected power), and the supply powers P₁ and P₂ with respect to the plasma decrease by that amount. That is, the supply power P₁ of the first frequency F₁ is lower than the first output power E₁ of the first frequency F₁ (P₁<E₁), and the supply power P₂ of the second frequency F₂ is lower than the second output power E₂ of the second frequency F₂ (P₂<E₂). Further, the total amount PT of the supply power supplied to the plasma is P₁+P₂ (<E₁+E₂). The impedance matching is achieved as each frequency approaches the first resonance point FP₁, and the supply power with respect to the plasma increases.

In order to minimize the effect on the plasma, the second output power E₂ of the second frequency F₂ is set to a power that is relatively small with respect to the first output power E₁ of the first frequency F₁ and that is detectable by the measurer 200. For example, when the first output power E₁ has a power of 100 W or more, the second output power E₂ is set to 0.1 to 1% (0.1 to 1 W), and the measurer 200 is configured to include a radio-frequency amplifier circuit and an A/D circuit having a gain and a resolution capable of detecting the power ranges thereof.

FIG. 6B illustrates steps (step ST10 and step ST12) of sweeping the second frequency F₂ from the F₂(1) to the F₂(2), calculating a power spectrum between F₂(1) and F₂(2), and searching for the first resonance point FP₁. When the second frequency F₂ is swept from F₂(1) to F₂(2), the impedance is changed along with the sweep. In the illustrated examples, the impedance is reduced along with the sweep from the second frequency F₂(1) to the first resonance point FP₁. The impedance increases along with the sweep from the first resonance point FP₁ to the first antiresonance point RP₁. Further, the impedance is reduced again in a direction in which the frequency increases from the first antiresonance point RP₁. In this way, with the sweep of the second frequency F₂, the characteristics of the graphical waveform of the impedance can be acquired without affecting the maintenance of the plasma.

During the sweep of the second frequency F₂, the impedance is reduced, so that the reflected power decreases, and the supply power increases. In one embodiment, a power spectrum of the supply power P₂ of the second frequency F₂ is calculated, and a peak of the power spectrum, that is, a frequency at which the power is maximized (P_{2MAX}(1)) is regarded as the first resonance point FP₁. Further, in one embodiment, the total amount PT (P₁+P₂) of the supply power during the sweep is measured, and a frequency at which the total amount PT of the supply power is maximized (PT_{MAX}(1)) during the measurement is regarded as the first resonance point FP₁. Further, in one embodiment, a frequency at which the reflected power is minimized is regarded as the first resonance point FP₁. As a method of calculating the power spectrum of the supply power P₂ of the second frequency F₂, a method such as a discrete Fourier transform of a measurement signal or a heterodyne detection method used for a radio signal can be used.

Further, when the second frequency F₂ is swept, the first frequency F₁ is limited to a frequency at which the plasma can be stably maintained. The first frequency F₁ may be fixed during the sweep of the second frequency F₂. Alternatively, control of specifying the frequency at which the plasma can be stably maintained from an intermediate result of the search for the first resonance point FP₁, and moving the first frequency F₁ during the sweep of the second frequency F₂ may be performed. That is, by sweeping the second frequency F₂, a range of the frequency at which the plasma can be stably maintained is specified, and the first frequency F₁ is changed within the range. In the illustrated examples, since the impedance is gradually reduced from the second frequency F₂(1) to the first resonance point FP₁, it can be specified that the plasma can be stably maintained even when the first frequency F₁ is changed within these ranges. When the first frequency F₁ is changed, the change may be performed later than the sweep of the second frequency F₂ at a speed lower than a speed of the sweep of the second frequency F₂ (a speed of the frequency change). Alternatively, the change may be performed following the sweep of the second frequency F₂ at the same speed as the speed of the sweep of the second frequency F₂. As a result, the first resonance point FP₁ can be specified by sweeping the second frequency F₂ having a small effect on the maintenance of the plasma, while the plasma is stably maintained by the first output power E₁ of the first frequency F₁.

FIG. 6C illustrates a step (step ST14) of sweeping the first frequency F₁ and tuning the first frequency F₁ to the resonance point FP after the first resonance point FP₁ is specified. Since the first resonance point FP₁ is specified in advance by the sweep of the second frequency F₂, it is possible to suppress the first frequency F₁ from moving beyond the first resonance point FP₁ to the first antiresonance point RP₁ side during the sweep. As a result, the shortage of the supply power due to the rapid variation in the impedance at the first antiresonance point RP₁ is suppressed, and the matching control can be performed while the plasma is stabilized.

Next, steps of re-matching when the resonance point moves from the first resonance point FP₁ to the second resonance point FP₂ due to the variation in the impedance of the plasma after the first frequency F₁ is tuned to the first resonance point FP₁ (steps ST10 to ST18 executed again when the reflected power exceeds the threshold in step ST18) will be described with reference to FIGS. 7A to 7C.

FIG. 7A illustrates a state where, after the first frequency F₁(2) illustrated in FIG. 6C is tuned to the first resonance point FP₁, the first resonance point FP₁ moves to the second resonance point FP₂ due to the variation of the impedance of the plasma, and the reflected power exceeds the threshold. When the resonance point moves, the resonance point deviates from a matching point of the impedance, and the supply power with respect to the plasma decreases. In the steps of re-matching, the first frequency F₁ is matched to the second resonance point FP₂.

FIG. 7B illustrates steps of re-searching for and specifying the second resonance point FP₂ by sweeping the second frequency F₂ between F₂(3) and F₂(4) (steps ST10 and ST12 executed again when the reflected power exceeds the threshold in step ST18). In one embodiment, as in the step illustrated in FIG. 6B, a peak of a power spectrum of the supply power P₂ of the second frequency F₂, that is, a frequency at which the power is maximized (P_{2MAX}(2)) is regarded as the second resonance point FP₂. Further, in one embodiment, the total amount PT (P₁(2)+P₂(2)) of the supply power is measured during the sweep of the second frequency F₂, and the frequency at which the total amount PT of the supply power is maximized (PT_{MAX}(2)) is regarded as the second resonance point FP₂. Further, in one embodiment, a frequency at which the reflected power is minimized is regarded as the second resonance point FP₂.

FIG. 7C illustrates a step of sweeping the first frequency F₁(2) in a direction of the specified second resonance point FP₂ and tuning to the second resonance point FP₂ (step ST14 executed again when the reflected power exceeds the threshold in step ST18).

Through the steps illustrated in FIGS. 7A to 7C, the second resonance point FP₂ can be specified, and the first frequency F₁ can be tuned, even when the first resonance point FP₁ moves to the second resonance point FP₂.

### Second Embodiment

Hereinafter, the plasma processing method MT2 according to the second embodiment will be described with reference to the drawings. In the plasma processing method MT2 according to the second embodiment, the frequency F₁₁ of the output power E₁₁ that maintains the plasma has the bandwidth ΔF. That is, the output power E₁₁ of the frequency F₁₁ that maintains the plasma is also used for searching for the resonance point of the impedance, and the bandwidth ΔF of the frequency F₁₁ is adjusted during the search for the resonance point. Accordingly, the frequency F₁₁ is asymptotically tuned to the resonance point. Here, the “frequency F₁₁ has the bandwidth ΔF” indicates that the frequency F₁₁ includes two or more frequency components, and a difference between the frequencies of the highest-frequency component and the lowest-frequency component is ΔF. Hereinafter, a specific method will be described in detail.

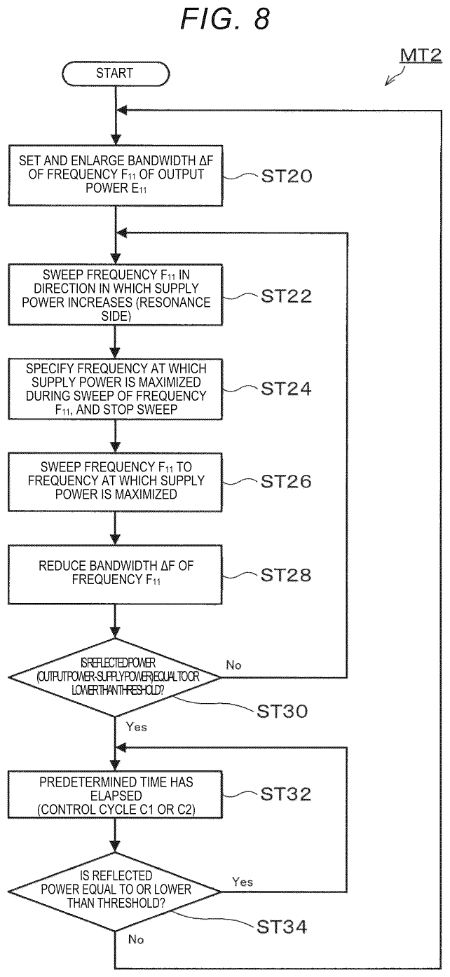

FIG. 8 is a flowchart illustrating a schematic diagram of the plasma processing method MT2 according to the second embodiment. In FIG. 8, first, the bandwidth ΔF of the frequency F₁₁ of the output power E₁₁ is set (step ST20). In step ST20 when repeatedly executed in step ST34, which will be described later, the bandwidth ΔF is enlarged. Next, the frequency F₁₁ is swept in the direction (resonance side) in which the supply power increases (step ST22). Next, the frequency at which the supply power P₁₁ is maximized during the sweep of the frequency F₁₁ is specified, and the sweep is stopped (step ST24). Next, the frequency F₁₁ is swept and tuned to the frequency at which the specified supply power P₁₁ is maximized (step ST26). Next, the bandwidth ΔF of the frequency F₁₁ is reduced (step ST28). Next, the reflected power is compared with a threshold to determine the magnitude (step ST30). When the reflected power is equal to or lower than the threshold in step ST30, the process proceeds to step ST32. When the reflected power exceeds the threshold in step ST30, the process returns to step ST22. In step ST32, after the desired time (any one of the first control cycle C1 or the second control cycle C2) has elapsed, the process proceeds to step ST34 (step ST32). Next, the reflected power is compared with a threshold to determine the magnitude (step ST34). When the reflected power is equal to or lower than the threshold in step ST34, the process returns to step ST32. When the reflected power exceeds the threshold in step ST34, the process returns to step ST20. By repeating steps ST20 to ST34 to periodically perform the matching control, the frequency F₁₁ can be made to follow the movement of the resonance point due to the variation in the impedance and can be tuned.

The first control cycle C1 and the second control cycle C2 in step ST32 are the same as the first control cycle C1 and the second control cycle C2 described in the first embodiment.

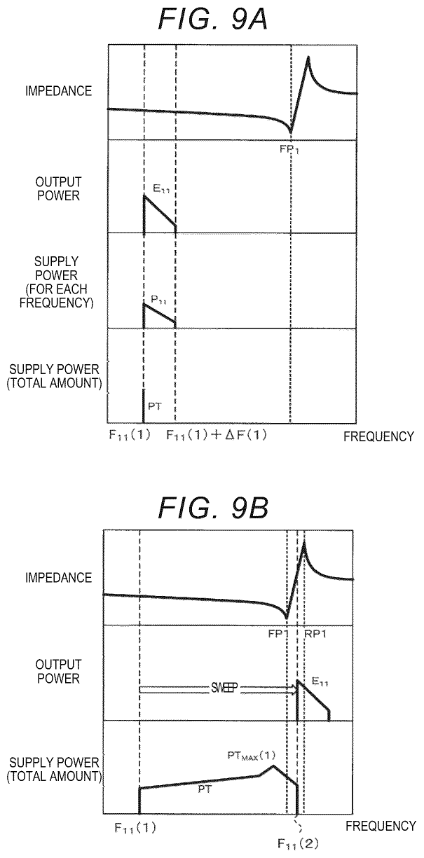

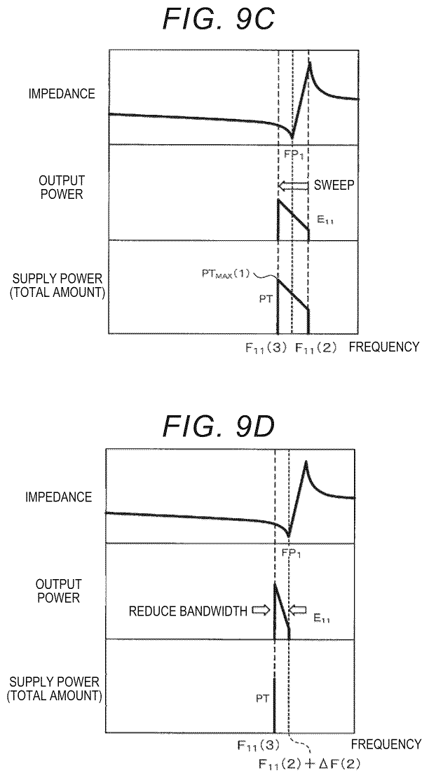

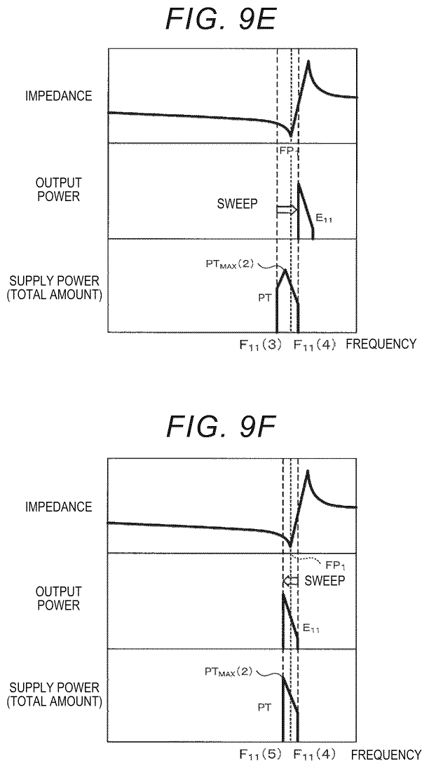

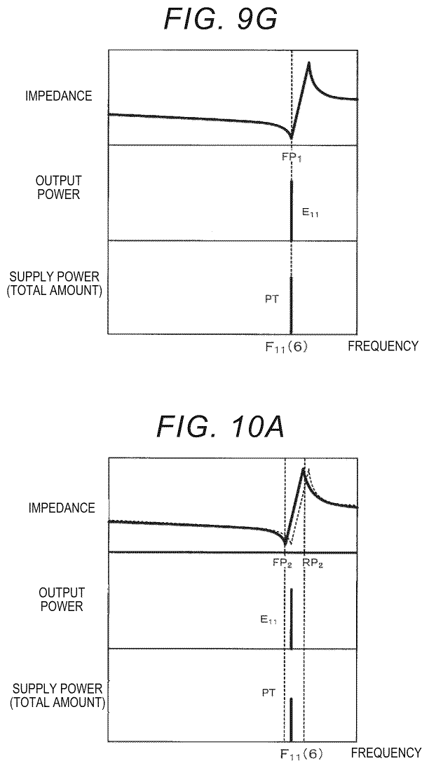

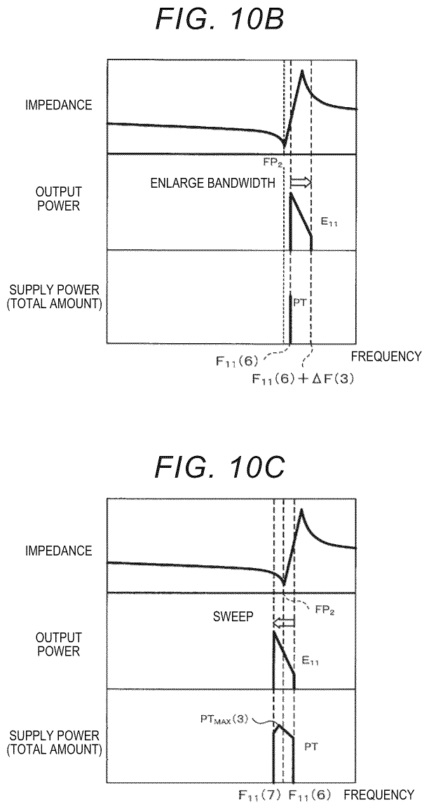

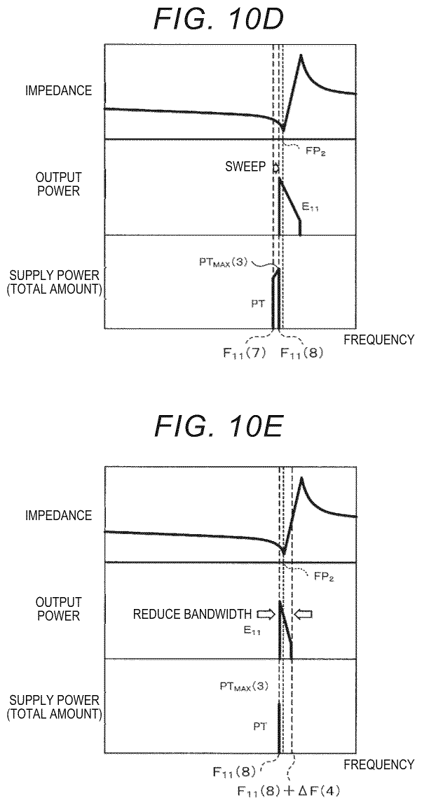

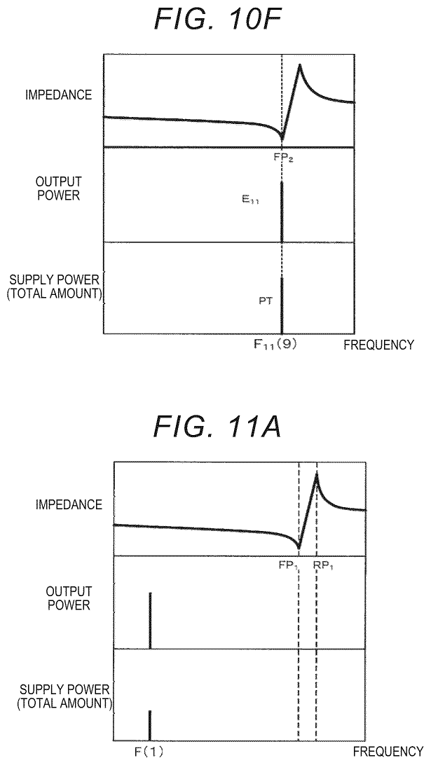

Hereinafter, the details and the significance of each step of the plasma processing method MT2 according to the second embodiment will be described with reference to FIGS. 9 and 10. In each of FIGS. 9 and 10, the graphs illustrate, from the top, the impedance between the source RF power source 31a and the plasma, the output power E₁₁ of the frequency F₁₁, the supply power P₁₁ of the frequency F₁₁, and the total amount PT of the supply power. The graph of the impedance is a graph for the sake of convenience of describing the details and the significance of each step of the plasma processing method MT2, and does not mean that the impedance at any frequency is measured or calculated in each step.

FIG. 9A illustrates the impedance of each frequency, the output power E₁₁ of the frequency F₁₁, the supply power P₁₁ for each frequency, and the total amount PT of the supply power when the bandwidth ΔF is set to the initial value ΔF(1) in step ST20. Here, the first frequency Fu has the bandwidth ΔF(1) from the lowest-frequency component F₁₁(1) to the highest-frequency component F₁₁(1)+ΔF(1). The supply power with respect to the plasma is dispersed between F₁₁(1) and F₁₁(1)+ΔF(1). Further, the integrated amount of the supply power P₁₁ is the total amount PT of the supply power with respect to the plasma. In the graphs in and after FIG. 9B, only the graph of the total amount PT of the supply power as the integrated amount of the supply power P₁₁ is illustrated, and the graph of the supply power P₁₁ is omitted.

The initial value ΔF(1) of the bandwidth ΔF will be described. In a plasma processing apparatus of an ICP method in which a reference frequency of the source RF power source 31a is 13 MHZ or 27 MHZ, the width of the frequency between the resonance point and the antiresonance point is assumed to be, for example, 10 KHZ to 100 KHZ. Therefore, it is preferable that the initial value ΔF(1) of the bandwidth is also 10 KHZ to 100 KHZ. However, when the width of the frequency between the resonance point and the antiresonance point is outside the above-described range depending on the conditions of the chamber pressure and the gas, an actual width of the frequency between the resonance point and the antiresonance point may be calculated, and the initial value ΔF(1) of the bandwidth may be calculated. Alternatively, the width (full width at half maximum) of the frequency that gives an impedance value that is half of the peak value may be calculated on both sides of the peak of the impedance at the resonance point, and the initial value ΔF(1) of the bandwidth may be determined such that the width does not fall below the full width at half maximum.

FIG. 9B illustrates a step (step ST22) of sweeping the frequency F₁₁ such that the frequency component with the lowest-frequency (the frequency component in which the power illustrated in the graph of the output power is maximized) changes from F₁₁(1) to F₁₁(2), and searching for the frequency at which the total amount PT of the supply power is maximized (PT_{MAX}(1)). In the sweep of the frequency F₁₁, the frequency is increased (or decreased) for each frequency component, while the bandwidth ΔF(1) and the power value of each frequency component are maintained. As a result, the graphic shape of the output power E₁₁ is not changed before the sweep and after the sweep.

In FIG. 9B, in the output power E₁₁, the output power E₁₁ is configured such that the lowest-frequency component is the maximum power, the highest-frequency component is the minimum power, and the power is gradually reduced from the lowest-frequency to the highest-frequency. As a result, even when the highest-frequency component moves to the first antiresonance point RP₁ side during the sweep, the plasma is maintained by the lowest-frequency component still located on the first resonance point FP₁ side.

In FIG. 9B, the total amount PT of the supply power is maximized before the lowest-frequency component exceeds the first resonance point FP₁ during the sweep. In other words, in step ST24, the frequency at which the total amount PT of the supply power is maximized (PT_{MAX}(1)) is specified before the lowest-frequency component exceeds the first resonance point FP₁. Hereinafter, the reason therefor will be described. The reflected power is generated for each frequency component in correlation with the power of each frequency component on the output path from the source RF power source 31a. That is, after the highest-frequency component passes beyond the first resonance point FP₁, the reflected power of the highest-frequency component increases in correlation with the power of the highest-frequency component. Meanwhile, the lowest-frequency component that has not yet reached the first resonance point FP₁ at that time approaches the first resonance point FP₁, so that the reflected power decreases in correlation with the power of the lowest-frequency component. Therefore, even after the highest-frequency passes beyond the first resonance point FP₁, the total amount of the reflected power decreases for a while, and the total amount PT of the supply power increases. Thereafter, the sweep proceeds, and when the frequency component of a certain degree passes beyond the first resonance point FP₁, the increase amount of the reflected power applied to the frequency component passing beyond the first resonance point FP₁ exceeds the decrease amount of the reflected power applied to the frequency component that has not yet reached the first resonance point FP₁. When the increase amount of the reflected power exceeds the decrease amount, the total amount of the supply power begins to decrease. Therefore, the total amount PT of the supply power is maximized before the lowest-frequency component passes beyond the first resonance point FP₁.

Further, in FIG. 9B, the frequency F₁₁(2) that is a stop point of the sweep may be set to a time when the frequency at which the total amount PT of the supply power is maximized (PT_{MAX}(1)) is specified. In this case, the determination as to whether the total amount PT of the supply power is maximized (PT_{MAX}(1)) may be performed when the desired power (for example, 10 W to 20 W) is reduced after the total amount PT of the supply power begins to decrease, and the frequency at which the total amount PT of the supply power is maximized (PT_{MAX}(1)) at that time may be specified. That is, in this case, in step ST22, “sweeping the frequency F₁₁ in a direction (resonance side) in which the supply power increases” includes sweeping the frequency F from the time when the supply power begins to decrease to the time when the desired power decreases. Alternatively, a threshold for the total amount PT of the supply power may be set such that the total amount PT of the supply power due to the frequency F₁₁ does not fall below the power required for the plasma maintenance, and the stop point of the sweep may be determined based on the threshold. Alternatively, a threshold for the reflected power may be set such that the source RF power source 31a does not exceed a value of an acceptable reflected power, and the stop point of the sweep may be determined based on the threshold.

FIG. 9C illustrates a step (step ST26) of sweeping the frequency component (frequency component in which the power illustrated in the graph of the output power is maximized) having the lowest-frequency from F₁₁(2) to the frequency F₁₁(3) in which the supply power is maximized (PT_{MAX}(1)). At the time after the sweep, the highest-frequency components may exceed the first resonance point FP₁.

FIG. 9D illustrates a step (step ST28) of reducing the bandwidth ΔF(1) of the frequency F₁₁ to ΔF(2). When the bandwidth ΔF is reduced in step ST28, it is preferable that the total amount of the output power of the frequency F₁₁ is not changed before and after the reduction. In the embodiment illustrated in FIG. 9D, the bandwidth ΔF is reduced, and the power of the frequency component having the lowest-frequency is increased, so that the total amount of the output power of the frequency F₁₁ is not changed before and after the reduction.

In FIG. 9D, the reduction amount of the bandwidth ΔF may be determined based on a desired control target number of times until the reflected power determined in step ST30 is equal to or lower than the threshold. As an example, in a case where the control target number of times is n times, when ΔF(1) is reduced to ΔF(2) in step ST28, ΔF(1)/n is subtracted from the bandwidth ΔF. Similarly, each time step ST28 is repeatedly executed in step ST30, ΔF(1)/n is subtracted from the bandwidth ΔF. That is, in this case, in the k-th step ST28 repeated in step ST30, the value of the bandwidth ΔF is ΔF(1)−k·ΔF(1)/n. As an example, when ΔF(1) is reduced to ΔF(2) in step ST28, 1/m is integrated with the bandwidth ΔF. Similarly, each time step ST28 is repeatedly executed in step ST30, ΔF is multiplied by 1/m. That is, in this case, in the k-th step ST28 repeated in step ST30, the value of the bandwidth ΔF is ΔF(1)/m^{k}.

FIG. 9E illustrates a step of sweeping the frequency F₁₁ from F₁₁(3) to F₁₁(4) and searching for the frequency at which the total amount PT of the supply power is maximized (PT_{MAX}(2)) (step ST22 when repeatedly executed in step ST30). In FIG. 9E, since the bandwidth ΔF is reduced from ΔF(1) to ΔF(2), the frequency at which the total amount PT of the supply power is maximized (PT_{MAX}(2)) is different from the frequency at which the total amount PT of the supply power is maximized (PT_{MAX}(1)) when the bandwidth ΔF is ΔF(1). However, also in this case, for the same reason as described above, the frequency at which the total amount PT of the supply power is maximized (PT_{MAX}(2)) is specified before the lowest-frequency component exceeds the first resonance point FP₁.

FIG. 9F illustrates a step of sweeping the frequency F₁₁ from F₁₁(4) to the frequency F₁₁(5) at which the total amount PT of the supply power is maximized (PT_{MAX}(2)) (step ST26 when repeatedly executed in step ST30). At the time after the sweep, the highest-frequency components may exceed the first resonance point FP₁.

Hereinafter, the descriptions with respect to FIGS. 9A to 9F will be summarized. By executing steps ST20 to ST28, the bandwidth ΔF of the frequency F₁₁ is reduced from ΔF(1) to ΔF(2) (FIGS. 9A to 9D). Next, when the reflected power exceeds the threshold in step ST30, the process returns to step ST22, and the sweep is executed again between the frequencies F(3) and F(4) to perform the search. As a result, a frequency that asymptotically approaches the first resonance point FP₁ (frequency at which the total amount PT of the supply power is maximized (PT_{MAX}(2))) than the frequency at which the total amount PT of the supply power is maximized (PT_{MAX}(1)) when the bandwidth ΔF is ΔF(1) is specified (FIG. 9E). Thereafter, the frequency F₁₁ more asymptotically approaches the first resonance point FP₁ by sweeping to the frequency (F₁₁(5)) at which the total amount PT of the specified supply power is maximized (PT_{MAX}(2)). Thereafter, the steps (steps ST22 to ST30) of FIGS. 9A to 9F are repeated a finite number of times, so that the frequency F₁₁ is tuned to the first resonance point FP₁. Further, the bandwidth ΔF of the frequency F₁₁ shifts from being broad to being single. The bandwidth ΔF being single is a concept that includes a finite width responsive to a frequency resolution measurable by a measuring instrument such as a spectrum analyzer.

FIG. 9G illustrates a state where the bandwidth ΔF approaches being single and the frequency F₁₁ is tuned to the first resonance point FP₁ by repeating the steps (steps ST22 to ST30) of FIGS. 9A to 9F. In the impedance matching state where the frequency F₁₁ is tuned to the first resonance point FP₁, the supply power with respect to the plasma may be maximized.

Next, steps of re-matching when the resonance point moves from the first resonance point FP₁ to the second resonance point FP₂ due to the variation in the impedance of the plasma after the frequency F₁₁ is tuned to the first resonance point FP₁ (steps ST20 to ST34 repeatedly executed again when the reflected power exceeds the threshold in step ST34) will be described with reference to FIGS. 10A to 10F

FIG. 10A illustrates a state where, after the frequency F₁₁ is tuned to the first resonance point FP₁ as illustrated in FIG. 9G, the first resonance point FP₁ moves to the second resonance point FP₂ due to the variation of the impedance of the plasma, and the reflected power exceeds the threshold. When the resonance point moves, the resonance point deviates from a matching point of the impedance, and the supply power with respect to the plasma decreases. In the steps of re-matching, the frequency F₁₁ is matched to the second resonance point FP₂.

FIG. 10B illustrates a step of enlarging the bandwidth ΔF of the frequency F₁₁ to ΔF(3) (step ST20 when repeatedly executed in step ST34). The frequency F₁₁(6) at the time of tuning to the first resonance point FP₁ may approach the second antiresonance point RP₂ due to the variation in the impedance. In this case, enlarging the bandwidth ΔF may decrease the supply power with respect to the plasma, which may cause the misfire of the plasma. Therefore, in this case, the supply power with respect to the plasma is monitored when the bandwidth ΔF is enlarged, and the adjustment or the determination is performed such that the bandwidth ΔF in which the power enough to maintain the plasma can be supplied is obtained. Alternatively, the bandwidth ΔF may be adjusted after the sweep of the frequency F₁₁ in a direction of the second resonance point FP₂ side, in which the change in the impedance is gradual as compared to the impedance of the second antiresonance point RP₂ side.

FIG. 10C illustrates steps of sweeping the frequency F₁₁(6) to F₁₁(7) on the second resonance point FP₂ side, and searching for the frequency at which the total amount PT of the supply power is maximized (PT_{MAX}(3)) (steps ST22 and ST24 when repeatedly executed in step ST34).

FIG. 10D illustrates a step of sweeping from the frequency F₁₁(7) to the frequency F₁₁(8) at which the total amount PT of the supply power is maximized (PT_{MAX}(3)) (step ST26 when repeatedly executed in step ST34).

FIG. 10E illustrates a step of reducing the bandwidth ΔF(3) of the frequency F₁₁(8) to ΔF(4) (step ST28 when repeatedly executed in step ST34).

FIG. 10F illustrates a state where the frequency F₁₁ is tuned to the second resonance point FP₂ by repeating the steps (step ST22 to step ST28) illustrated in FIGS. 10C to 10E.

The details and the significance of the steps illustrated in FIGS. 10D to 10F are the same as the details and the significance of the steps described above with reference to FIGS. 9C to 9G.

Even when the resonance point moves from the first resonance point FP₁ to the second resonance point FP₂ due to the variation in the impedance through the steps of re-matching illustrated in FIGS. 10A to 10F described above, the frequency F₁₁ can be tuned to the second resonance point FP₂, and the bandwidth ΔF thereof can be made single. In the impedance matching state where the frequency F₁₁ is tuned to the second resonance point FP₂, the supply power with respect to the plasma may be maximized.

While the preferred embodiments of the present disclosure have been described above, it is possible to obtain preferred effects by combining and applying the first embodiment and the second embodiment. As examples, in the plasma processing method MT1 according to the first embodiment, the first frequency F₁ may have the bandwidth ΔF, and the sweep of the first frequency F₁ may be made the same as the sweep of the frequency F₁₁ in the plasma processing method MT2 according to the second embodiment.

Further, the present disclosure is not limited to the above-described embodiments, and modifications and changes may be made within the scope of the gist. As an example, the above-described embodiments have been mainly described by using the etching apparatus using the plasma, but the present disclosure can also be applied to a processing apparatus or manufacturing method such as a semiconductor or a liquid crystal display using plasma such as CVD or ashing, or to another processing apparatus or manufacturing method requiring an impedance matching process of a radio-frequency power source.

For example, the components of the above-described embodiments may be combined as desired. From the desired combination, functions and effects of each component related to the combination can be obtained as a matter of course, and other functions and effects apparent to those skilled in the art can be obtained from the description herein. The effects described herein are merely illustrative or exemplary, and are not limited. In other words, the technique according to the present disclosure may have other effects apparent to those skilled in the art from the description herein, in addition to or in place of the effects described above.

1. A plasma processing apparatus comprising:
a plasma processing chamber;
an antenna disposed in an upper portion of the plasma processing chamber or above the plasma processing chamber;
an RF power source electrically connected to the antenna and configured to control a frequency of an output power; and
a controller having a processor and a memory with a computer readable program stored therein,
wherein the RF power source is configured to output a first output power having a first frequency, and a second output power having a second frequency of a smaller power than an output power having the first frequency, and
the controller is configured to execute:
(a) sweeping the second frequency and searching for and specifying a resonance point; and
(b) tuning the first frequency to the resonance point.

2. The plasma processing apparatus according to claim 1,
wherein the controller is configured to, in the (a), sweep the second frequency in a direction in which a supply power with respect to the plasma processing chamber is maximized, and specify a frequency at which the supply power is maximized, as the resonance point.

3. The plasma processing apparatus according to claim 1,
wherein the controller is configured to, in the (a), control the first frequency to a state selected from any one of following (a1) to (a3):
(a1) the first frequency is fixed;
(a2) the first frequency is changed later than the sweep of the second frequency within a range in which the second frequency is swept; and
(a3) the first frequency is changed following the sweep of the second frequency within the range in which the second frequency is swept.

4. The plasma processing apparatus according to claim 1,
wherein the controller is configured to:
execute (c) comparing, after tuning the first frequency to the resonance point, a reflected power with a threshold after a first control cycle has elapsed when a plasma is in a transient state, and after a second control cycle has elapsed when the plasma is in a steady state; and
when the reflected power exceeds the threshold in the (c), execute the (a) and the (b) again.

5. A plasma processing method using a plasma processing apparatus including:
a plasma processing chamber;
an antenna disposed in an upper portion of the plasma processing chamber or above the plasma processing chamber; and
an RF power source electrically connected to the antenna and configured to control a frequency of an output power, the plasma processing method comprising:
outputting, by the RF power source, a first output power having a first frequency, and a second output power having a second frequency of a smaller power than an output power having the first frequency;
(a) sweeping the second frequency and searching for and specifying a resonance point; and
(b) tuning the first frequency to the resonance point.

6. The plasma processing method according to claim 5,
wherein, in the (a), the second frequency is swept in a direction in which a supply power with respect to the plasma processing chamber is maximized, and a frequency at which the supply power is maximized is specified as the resonance point.

7. The plasma processing method according to claim 5,
wherein, in the (a), the first frequency is controlled to a state selected from any one of following (a1) to (a3):
(a1) the first frequency is fixed;
(a2) the first frequency is changed later than the sweep of the second frequency within a range in which the second frequency is swept; and
(a3) the first frequency is changed following the sweep of the second frequency within the range in which the second frequency is swept.

8. The plasma processing method according to claim 5, further comprising:
(c) comparing, after tuning the first frequency to the resonance point, a reflected power with a threshold after a first control cycle has elapsed when a plasma is in a transient state, and after a second control cycle has elapsed when the plasma is in a steady state,
wherein, when the reflected power exceeds the threshold in the (c), the (a) and the (b) are executed again.

9. A plasma processing apparatus comprising:
a plasma processing chamber;
an antenna disposed in an upper portion of the plasma processing chamber or above the plasma processing chamber;
an RF power source electrically connected to the antenna and configured to control a frequency of an output power; and
a controller having a processor and a memory with a computer readable program stored therein,
wherein the RF power source is configured to output an output power having a bandwidth in which a frequency includes two or more frequency components, and
the controller is configured to execute:
(a) setting the bandwidth of the frequency of the output power to a first bandwidth, sweeping the frequency, and specifying a first frequency at which a supply power with respect to the plasma processing chamber is maximized; and
(b) setting the bandwidth to a second bandwidth narrower than the first bandwidth, sweeping the frequency of the output power, and specifying a second frequency at which the supply power with respect to the plasma processing chamber is maximized.

10. The plasma processing apparatus according to claim 9,
wherein the controller is configured to:
execute (c) comparing a reflected power with a threshold after specifying the second frequency at which the supply power with respect to the plasma processing chamber is maximized in the (b); and
when the reflected power exceeds the threshold in the (c), execute the (a) and the (b) again.

11. The plasma processing apparatus according to claim 10,
wherein the controller is configured to:
execute (d) comparing, when the reflected power is equal to or lower than the threshold in the (c), the reflected power with the threshold after the first control cycle has elapsed when the plasma is in a transient state, and after the second control cycle has elapsed when the plasma is in a steady state; and
when the reflected power exceeds the threshold in the (d), execute the (a) to the (c) again.

12. A plasma processing method using a plasma processing apparatus including:
a plasma processing chamber;
an antenna disposed in an upper portion of the plasma processing chamber or above the plasma processing chamber; and
an RF power source electrically connected to the antenna, the method comprising:
outputting, by the RF power source, an output power having a bandwidth in which a frequency includes two or more frequency components;
(a) setting the bandwidth of the frequency of the output power to a first bandwidth, sweeping the frequency, and specifying a first frequency at which a supply power with respect to the plasma processing chamber is maximized; and
(b) setting the bandwidth to a second bandwidth narrower than the first bandwidth, sweeping the frequency of the output power, and specifying a second frequency at which the supply power with respect to the plasma processing chamber is maximized.

13. The plasma processing method according to claim 12, further comprising:
(c) comparing a reflected power with a threshold after specifying the second frequency at which the supply power with respect to the plasma processing chamber is maximized in the (b),
wherein, when the reflected power exceeds the threshold in the (c), the (a) and the (b) are executed again.

14. The plasma processing method according to claim 13, further comprising:
(d) comparing, when the reflected power is equal to or lower than the threshold in the (c), the reflected power with the threshold after the first control cycle has elapsed when the plasma is in a transient state, and after the second control cycle has elapsed when the plasma is in a steady state,
wherein, when the reflected power exceeds the threshold in the (d), the (a) to the (c) are executed again.

15. The plasma processing method according to claim 12, further comprising:
controlling monitoring of the supply power with respect to the plasma and periodically adjusting the frequency of the output power.

16. The plasma processing method according to claim 13, further comprising:
controlling monitoring of the supply power with respect to the plasma and periodically adjusting the frequency of the output power.

17. The plasma processing apparatus according to claim 2, wherein the controller is configured to control monitoring of the supply power with respect to the plasma and periodically adjusting the frequency of the output power.

18. The plasma processing method according to claim 6, further comprising:
controlling monitoring of the supply power with respect to the plasma and periodically adjusting the frequency of the output power.

19. The plasma processing apparatus according to claim 9, wherein the controller is configured to control monitoring of the supply power with respect to the plasma and periodically adjusting the frequency of the output power.

20. The plasma processing apparatus according to claim 10, wherein the controller is configured to control monitoring of the supply power with respect to the plasma and periodically adjusting the frequency of the output power.
